(19) United States
(12) Patent Application Publication
(10) Pub. No.: US 2024/0194500 A1
(43) Pub. Date: Jun. 13, 2024

(54) SUBSTRATE PROCESSING APPARATUS AND METHOD

(71) Applicant: SEMES CO., LTD., Cheonan-si (KR)

(72) Inventors: Seonggil Lee, Hwaseong-si (KR); Wanjae Park, Hwaseong-si (KR); Dongsub Oh, Busan-si (KR); Myoungsub Noh, Hwaseong-si (KR); Hyejoon Kheel, Hwaseong-si (KR)

(73) Assignee: SEMES CO., LTD., Cheonan-si (KR)

(21) Appl. No.: 18/536,378

(22) Filed: Dec. 12, 2023

(30) Foreign Application Priority Data
Dec. 13, 2022 (KR) 10-2022-0174188

(51) Int. Cl. H01L 21/67; H01J 37/32; H01L 21/3065

(52) U.S. Cl. CPC H01L 21/67069; H01J 37/32449; H01J 37/32477; H01L 21/3065; H01L 21/67248; H01J 2237/334

(57) ABSTRACT

A substrate processing apparatus includes a plasma space, a processing space, a first gas supplier configured to supply first source gas to the plasma space, and a second gas supplier configured to supply second process gas to the processing space. The first source gas supplies first process gas for etching a first etch target layer in the processing space. The second process gas etches a second etch target layer in the processing space. The first gas supplier and the second gas supplier are separated from each other.

### CROSS-REFERENCE TO RELATED APPLICATION

This application is based on and claims priority under 35 U.S.C. § 119 to Korean Patent Application No. 10-2022-174188, filed on Dec. 13, 2022, in the Korean Intellectual Property Office, the disclosure of which is incorporated by reference herein in its entirety.

### BACKGROUND

### 1. Field

The disclosure relates to a substrate processing apparatus, and more particularly, to a substrate processing apparatus that performs an etching process.

### 2. Description of the Related Art

To manufacture semiconductor devices, desired patterns are formed on a substrate by performing various processes, such as photolithography, etching, ashing, ion implantation, thin-film deposition, and cleaning, on the substrate. Among them, etching is a process of removing a selected heating area from a layer formed on the substrate. Wet etching and dry etching are used.

An etching device using plasma is used for dry etching. In general, in order to form plasma, an electromagnetic field is formed in an internal space of a chamber and excites process gas provided in the chamber to a plasma state.

Plasma refers to an ionized gas state including ions, electrons, radicals, and the like. Plasma is generated by very high temperatures, strong electric fields, or radio frequency (RF) electromagnetic fields. A semiconductor device manufacturing process uses plasma to perform an etching process.

### SUMMARY

Provided is a substrate processing apparatus in which an etching selectivity of different materials is controlled.

Provided is a substrate processing method in which an etching selectivity of different materials is controlled.

The objectives of the disclosure are not limited to those described above, and other objectives that are not mentioned herein will be understood from the following description by those of ordinary skill in the art.

Additional aspects will be set forth in part in the description which follows and, in part, will be apparent from the description, or may be learned by practice of the presented embodiments of the disclosure.

According to embodiments, a substrate processing apparatus is provided. The substrate processing apparatus includes a plasma space, a processing space, a first gas supplier configured to supply first source gas to the plasma space, and a second gas supplier configured to supply second process gas to the processing space, wherein the first source gas supplies first process gas for etching a first etch target layer in the processing space, the second process gas etches a second etch target layer in the processing space, and the first gas supplier and the second gas supplier are separated from each other.

According to embodiments, a substrate processing apparatus is provided. The substrate processing apparatus includes a plasma space, a processing space in which a first etch target layer and a second etch target layer are disposed, a first gas supplier configured to supply first source gas to the plasma space, and a second gas supplier configured to supply second source gas to the processing space, wherein the first source gas generates first process gas in the plasma space, the second source gas supplies second process gas to the processing space, the first process gas etches the first etch target layer, the second process gas etches the second etch target layer, and a degree of etching of the second etch target layer relative to the first etch target layer is adjusted by adjusting a ratio of the second source gas to the first source gas.

According to embodiments, a substrate processing method is provided. The substrate processing method includes supplying first source gas to a plasma space, allowing the first source gas to generate first process gas in the plasma space, etching a first etch target layer by supplying the first process gas to a processing space, etching a second etch target layer by supplying, to the processing space, second source gas that supplies second process gas, and adjusting a degree of etching of the second etch target layer relative to the first etch target layer by adjusting a ratio of the second source gas to the first source gas.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a substrate processing apparatus according to an embodiment;

FIGS. 2 and 3 are cross-sectional views illustrating substrate processing apparatuses according to some embodiments;

FIGS. 4 to 6 are cross-sectional views of some elements of a substrate processing apparatus, according to embodiments;

FIGS. 7A to 7C are cross-sectional views illustrating a process of etching an etch target layer, according to embodiments;

FIGS. 8A to 8C are cross-sectional views illustrating a process of etching an etch target layer, according to embodiments; and

FIG. 9 is a flowchart showing a substrate processing method according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. Advantages and features of the disclosure, and methods of achieving them will be clarified with reference to embodiments of the disclosure described below in detail with reference to the accompanying drawings. However, the disclosure is not limited to embodiments provided below and may be implemented in various different forms. Rather, embodiments are provided so that the disclosure will be thorough and complete and will fully convey the concept of the embodiments of the disclosure to those of ordinary skill in the art. The disclosure is only defined by the scope of the claims. The same reference numerals denote the same elements throughout the specification.

Unless defined otherwise, all terms (including technical and scientific terms) as used herein have the same meaning as commonly understood by those of ordinary skill in the art. It will be understood that terms, such as those defined in commonly used dictionaries, will not be interpreted in an idealized or overly formal sense unless expressly so defined herein.

Hereinafter, embodiments will be described in detail with reference to the accompanying drawings. When describing the embodiments with reference to the accompanying drawings, the same or corresponding elements are denoted by the same reference numerals, and redundant descriptions thereof will be omitted.

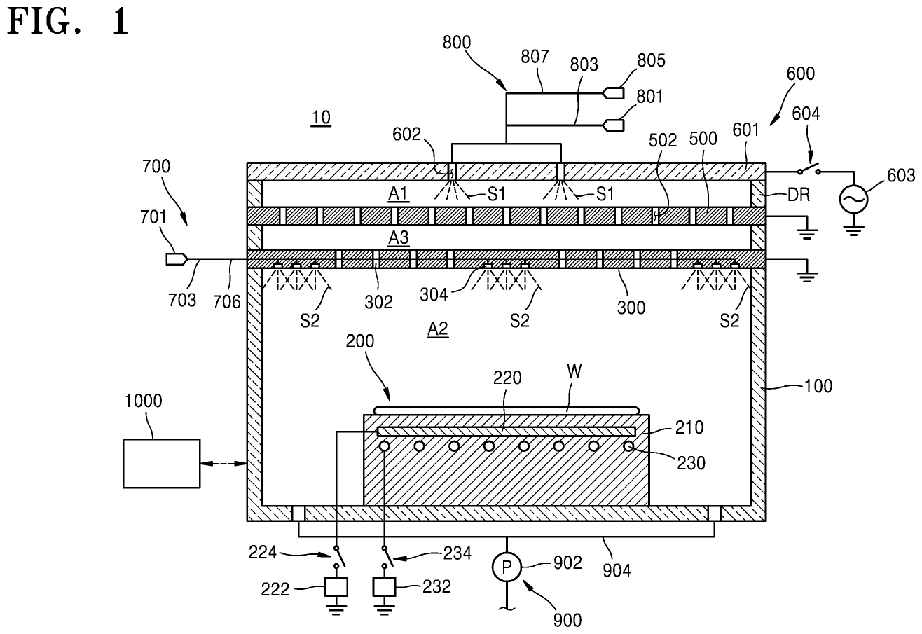

FIG. 1 is a cross-sectional view illustrating a substrate processing apparatus 10 according to an embodiment.

Referring to FIG. 1, the substrate processing apparatus 10 according to an embodiment may process a substrate W. The substrate processing apparatus 10 may process the substrate W by using plasma. The substrate processing apparatus 10 may remove a thin-film formed on the substrate W by using plasma. For example, the substrate processing apparatus 10 may remove the thin-film formed on the substrate W by transferring an etchant to the substrate W. For example, the substrate processing apparatus 10 may remove a thin-film including silicon (Si) and formed on the substrate W. For example, the substrate processing apparatus 10 may remove a thin-film including silicon-germanium (Si—Ge) and formed on the substrate W. For example, the substrate processing apparatus 10 may etch the substrate W having Si, SiGe, SiO₂, Si₃N₄, and poly-Si layers without particle contamination. The substrate W may be a wafer.

The substrate processing apparatus 10 may include a housing 100, a chuck 200, a shower head 300, an ion filter 500, an insulating member DR, an electrode portion 600, gas suppliers 700 and 800, an exhaust portion 900, and a controller 1000.

The housing 100 and the shower head 300 may be combined with each other to define a processing space A2, which is a space where the substrate W is processed. The shower head 300, the housing 100, and the ion filter 500 may be combined with each other to define a buffer space A3, which is a space where neutral gas (radicals) from which ions have been removed from plasma are uniformly distributed. The ion filter 500, the insulating member DR, and an upper electrode 601 may be combined with each other to define a plasma space A1, which is a space where plasma is generated. The elements involved in defining the processing space A2, the buffer space A3, and the plasma space A1 may be collectively referred to as a chamber. The processing space A2 and the buffer space A3 may be in fluid communication with each other. The buffer space A3 and the plasma space A1 may be in fluid communication with each other. In addition, the plasma space A1 and the processing space A2 may be in fluid communication with each other through the buffer space A3.

The housing 100 may define the processing space A2. For example, the housing 100 may be combined with the shower head 300, which will be described below, to define the processing space A2. The housing 100 may have a cylindrical shape with an open upper portion. An inner wall of the housing 100 may be coated with a material that may prevent etching by neutral gas (radicals), plasma, or etchant, which will be described below. For example, the inner wall of housing 100 may be coated with a dielectric layer such as ceramic. For example, the inner wall of the housing 100 may be coated with a metal layer such as nickel (Ni) or aluminum (Al). The housing 100 may be grounded. In addition, the housing 100 may have an opening (not shown) to allow the substrate W to be loaded into or unloaded from the processing space A2. The opening may be selectively shielded by a door (not shown). In addition, a temperature control member (not shown) configured to control the temperature of the housing 100 may be provided on the inner wall of the housing 100. The temperature of the housing 100 may be adjusted to about 0° C. to about 200° C. by the temperature control member. For example, the temperature of the housing 100 may be adjusted to about 60° C. to about 110° C.

The chuck 200 may support the substrate W in the processing space A2. In addition, the chuck 200 may be an electrostatic chuck (ESC) capable of chucking the substrate W by using electrostatic force. The chuck 200 may include a support plate 210, an electrostatic electrode 220, and a temperature controller 230.

The support plate 210 may support the substrate W. The support plate 210 may have a support surface that supports the substrate W. The support plate 210 may include a dielectric. For example, the support plate 210 may include a ceramic material. The electrostatic electrode 220 may be provided within the support plate 210. The electrostatic electrode 220 may be provided at a position overlapping the substrate W, when viewed from above. When power is supplied to the electrostatic electrode 220, the electrostatic electrode 220 may form an electric field due to electrostatic force allowing the substrate W to be chucked. The electric field may transfer attractive force to the substrate W so that the substrate W is chucked in a direction toward the support plate 210.

In addition, the substrate processing apparatus 10, for example, the chuck 200, may include first power modules 222 and 224 that supply power to the electrostatic electrode 220. The first power modules 222 and 224 may include an electrostatic electrode power source 222 and an electrostatic electrode switch 224. Power may be supplied to the electrostatic electrode 220 according to the on/off state of the electrostatic electrode switch 224. When power is supplied to the electrostatic electrode 220, the substrate W may be chucked to the chuck 200 by electrostatic force.

The temperature controller 230 may cool the substrate W. The temperature controller 230 may cool the substrate W by lowering the temperature of the support plate 210. For example, the temperature controller 230 may control the temperature of the support plate 210 from about −20° C. to about 40° C.

In addition, the substrate processing apparatus 10, for example, the chuck 200, may include second power modules 232 and 234 that supply power to the temperature controller 230. The second power modules 232 and 234 may include a power source 232 and a power switch 234. Power may be supplied to the temperature controller 230 according to the on/off state of the power switch 234.

The shower head 300 may be disposed on the upper portion of the housing 100. The shower head 300 may be disposed between the ion filter 500, which will be described below, and the processing space A2. The shower head 300 may be disposed between the buffer space A3 and the processing space A2. The shower head 300 may be grounded. In addition, a plurality of holes 302 may be formed in the shower head 300. The hole 302 may be formed to extend from the upper surface to the lower surface of the shower head 300. That is, the hole 302 may be formed to pass through the shower head 300. The hole 302 may be in indirect fluid communication with the processing space A2 and the plasma space A1 to be described below. In addition, the hole 302 may allow the processing space A2 and the buffer space A3 to be described below to be in fluid communication with each other.

In addition, a gas inlet 304 may be formed in the shower head 300. The gas inlet 304 may be connected to a first gas line 706 to be described below. The gas inlet 304 may be configured to supply second source gas S2 toward the processing space A2. The gas inlet 304 may be configured to communicate with the processing space A2 but not communicate with the plasma space A1 and the buffer space A3.

The ion filter 500 may partition the plasma space A1 and the buffer space A3 (and may further indirectly partition the plasma space A1 and the processing space A2). The ion filter 500 may be disposed between the upper electrode 601 and the processing space A2. In addition, the ion filter 500 may be disposed between the processing space A2 and the plasma space A1.

The ion filter 500 may be grounded. The ion filter 500 may be grounded to remove (or collect) ions included in the plasma when the plasma generated in the plasma space A1 flows into the buffer space A3 and further into the processing space A2. The ion filter 500 may be disposed on a plasma flow path through which the plasma generated in the plasma space A1 flows toward the processing space A2. That is, because ions are removed from the plasma generated in the plasma space A1 while passing through the ion filter 500, the plasma may include substantially only neutral gas (radicals) in the buffer space A3.

In addition, the ion filter 500 may be grounded and may function as an opposite electrode to the upper electrode 601 to be described below. A plurality of through holes 502 may be formed in the ion filter 500. The through holes 502 may be formed to pass through the ion filter 500. The through holes 502 may provide fluid communication between the plasma space A1 and the buffer space A3. The through holes 502 may provide fluid communication between the plasma space A1 and the processing space A2.

The electrode portion 600 may generate plasma in the plasma space A1. The electrode portion 600 may include the upper electrode 601 and upper power modules 603 and 604.

The upper electrode 601 may have a plate shape. The upper electrode 601 may generate plasma. The upper power modules 603 and 604 may supply power to the upper electrode 601. The upper power modules 603 and 604 may include an upper power source 603, which is an RF source, and a lower power switch 604. Power may be supplied to the upper electrode 601 according to the on/off state of the upper power module 604. When power is supplied to the upper electrode 601, an electric field may be formed between the upper electrode 601 and the ion filter 500 functioning as the opposing electrode, and the first source gas S1 and/or inert gas to be described below may be excited in the plasma space A1. Accordingly, plasma may be generated. In addition, gas injection holes 602 may be formed in the upper electrode 601. The first gas supplier 800 to be described below may supply the first source gas S1 or the inert gas to the plasma space A1 through the gas injection holes 602. In addition, the insulating member DR including an insulating material may be disposed between the upper electrode 601 and the ion filter 500. The insulating member DR may have a ring shape, when viewed from above.

The gas suppliers 700 and 800 may supply gas. The gas suppliers 700 and 800 may include the first gas supplier 800 and the second gas supplier 700.

The first gas supplier 800 may supply the first source gas S1 to the plasma space A1. In addition, the first gas supplier 800 may supply the inert gas to the plasma space A1. The first gas supplier 800 may inject the first source gas S1 or the inert gas into the plasma space A1 and supply first process gas P1 or inert gas, which will be described below, to the buffer space A3 and the processing space A2. The first gas supplier 800 may include first gas sources 801 and 805 and first gas lines 803 and 807. Specifically, the first gas supplier 800 may include a first sub-gas source 801, a first sub-gas line 803, a second sub-gas source 805, and a second sub-gas line 807.

The first sub-gas source 801 may store and/or supply the first source gas S1. The first sub-gas line 803 may be connected to the first sub-gas source 801 so that the first source gas S1 supplied by the first sub-gas source 801 is supplied to the plasma space A1. The first sub-gas supply source 801 may supply the first source gas S1 including fluorine to the plasma space A1. For example, the first source gas S1 may be gas including at least one of NF₃, SF₆, SiF₄, and XeF₂. The second sub-gas source 805 may store and/or supply inert gas. The second sub-gas line 807 may be connected to the second sub-gas source 805 so that the inert gas supplied by the second sub-gas source 805 is supplied to the plasma space A1. The second sub-gas source 805 may supply inert gas including at least one of He, Ar, Xe, and N2 to the plasma space A1. For example, the inert gas may be gas including He.

The second gas supplier 700 may supply the second source gas S2 to the processing space A2. When plasma from which ions have been removed by the ion filter 500, that is, neutral gas (radicals) flows into the processing space A2, the second gas supplier 700 may supply the second source gas S2 to the processing space A2. Before plasma from which ions have been removed by the ion filter 500, that is, neutral gas (radicals) flows into the processing space A2 voltage second gas supplier 700 may supply the second source gas S2 to the processing space A2. The second gas supplier 700 may supply the second source gas S2 including fluorine gas (F₂). The second gas supplier 700 may include a second gas source 701, a main gas line 703, and a second gas line 706. The second gas source 701 may store and/or supply the second source gas S2. One end of the main gas line 703 may be connected to the second gas source 701, and the other end of the main gas line 703 may be branched to the second gas line 706. The first gas line 706 may be connected to the gas inlet 304 described above.

The second source gas S2 supplied by the second gas supplier 700 may be at least one of F₂, HF, SF₆, SiF₄, XeF₂, and NF₃. For example, the first source gas S1 may be gas including F₂.

The exhaust portion 900 may discharge gas supplied to the processing space A2, process by-products, and the like. The exhaust portion 900 may adjust the pressure of the processing space A2. The exhaust portion 900 may indirectly adjust the pressures of the buffer space A3 and the plasma space A1 by adjusting the pressure of the processing space A2. The exhaust portion 900 may adjust the pressure of the processing space A2 by discharging the atmosphere of the processing space A2, and may discharge gas supplied to the processing space A2 and process by-products generated in the process of processing the substrate W to the outside of the substrate processing apparatus 10. The exhaust portion 900 may include a pressure reducing member 902 and a pressure reducing line 904. The pressure reducing member 902 may be a pump. However, the pressure reducing member 902 is not limited thereto and may be variously modified. For example, known devices that provide reduced pressure may be used.

The controller 1000 may control the substrate processing apparatus 10, specifically, the elements of the substrate processing apparatus 10. For example, the controller 1000 may control the gas suppliers 700 and 800, the first power modules 222 and 224, the second power modules 232 and 234, the pressure reducing member 902, and the upper power modules 603 and 604.

The controller 1000 may include a process controller including a microprocessor (a computer) configured to control the substrate processing apparatus 10, a user interface including a keyboard configured to allow an operator to input commands so as to manage the substrate processing apparatus 10, a display configured to visualize and display the operation state of the substrate processing apparatus 10, and the like, and a storage configured to store a control program for executing the processes in the substrate processing apparatus 10 under the control of the process controller or a program (i.e., a process recipe) for processing the respective elements according to various data and processing conditions. In addition, the user interface and the storage may be connected to the process controller. The process recipe may be stored in a storage medium of the storage. The storage medium may be a hard disk, a portable disk such as compact disc read-only memory (CD-ROM) or digital versatile disc (DVD), or a semiconductor memory such as flash memory.

A substrate processing method according to an embodiment is described below. The substrate processing method described below may be performed by the substrate processing apparatus 10 described above. In addition, in order to perform the substrate processing method described below, the controller 1000 may control the elements of the substrate processing apparatus 10.

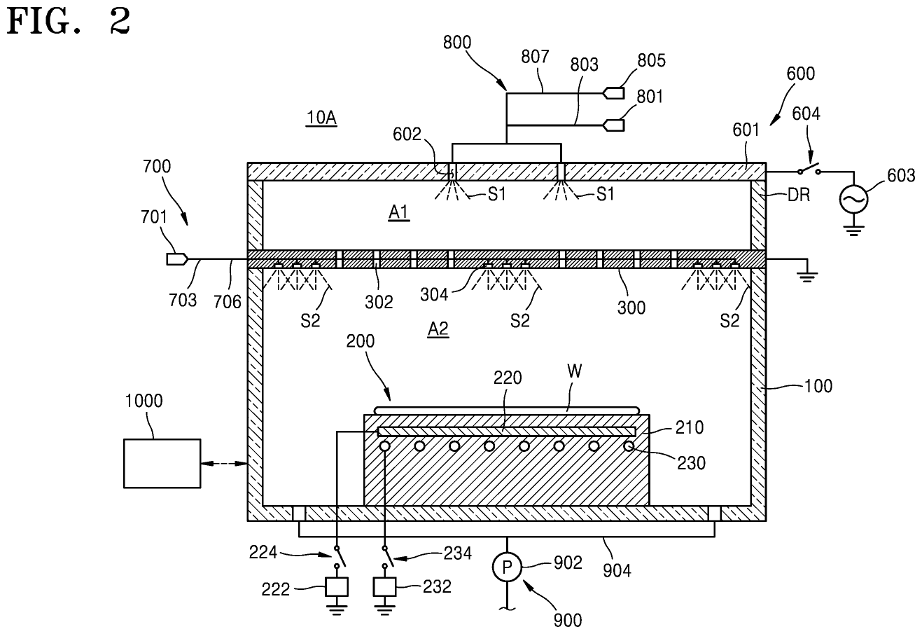

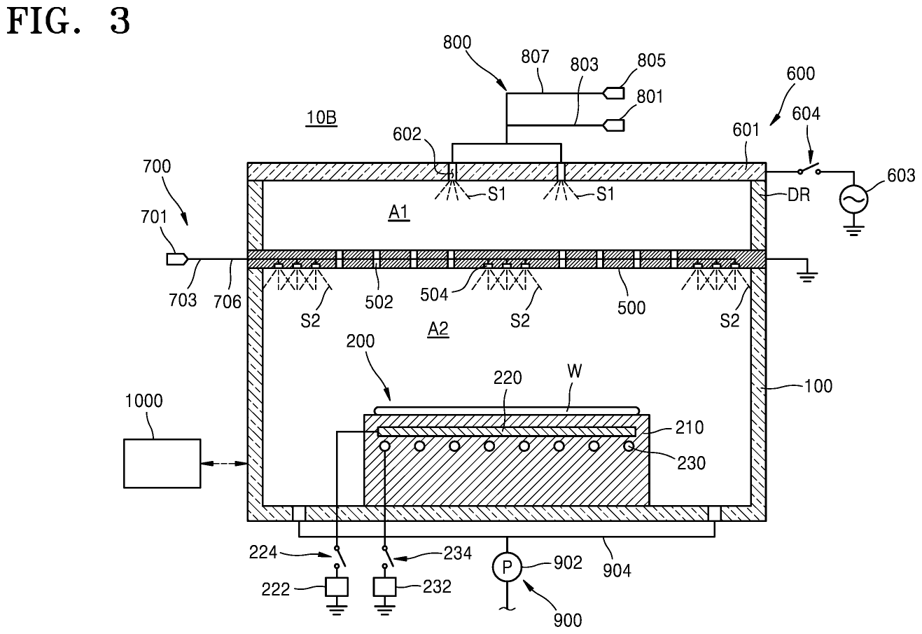

FIGS. 2 and 3 are cross-sectional views illustrating substrate processing apparatuses 10A and 10B according to some embodiments.

Referring to FIG. 2, the substrate processing apparatus 10A may include a plasma space A1 and a processing space A2. A first gas supplier 800 may be disposed in the plasma space A1 and configured to supply first source gas S1. A shower head 300 may be disposed between the plasma space A1 and the processing space A2 and supply second source gas S2 to the processing space A2.

Referring to FIG. 3, the substrate processing apparatus 10B may include a plasma space A1 and a processing space A2. A first gas supplier 800 may be disposed in the plasma space A1 and configured to supply first source gas S1. An ion filter 500 may be disposed between the plasma space A1 and the processing space A2 and configured to filter the first source gas S1. A gas inlet 504 connected to a second gas supplier 700 may be disposed in the ion filter 500 and configured to supply the second source gas S2 to the processing space A2.

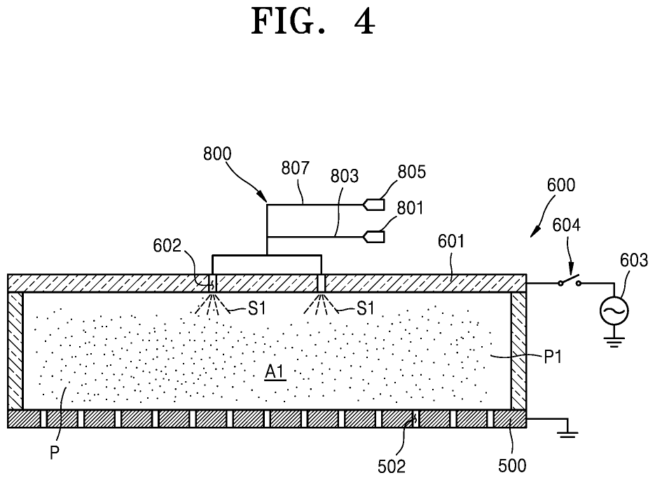

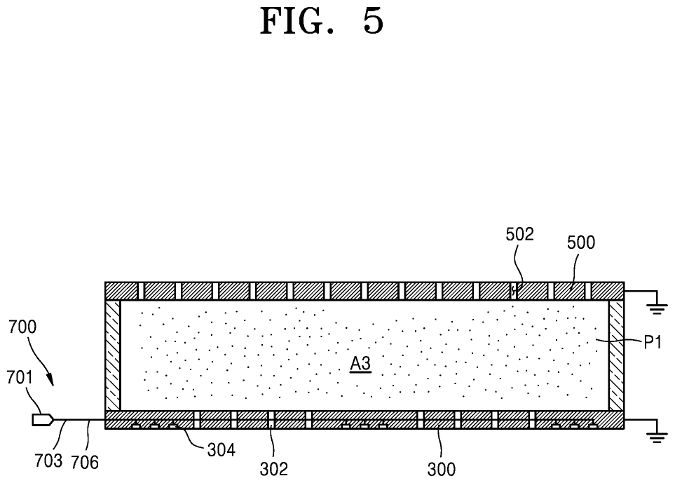

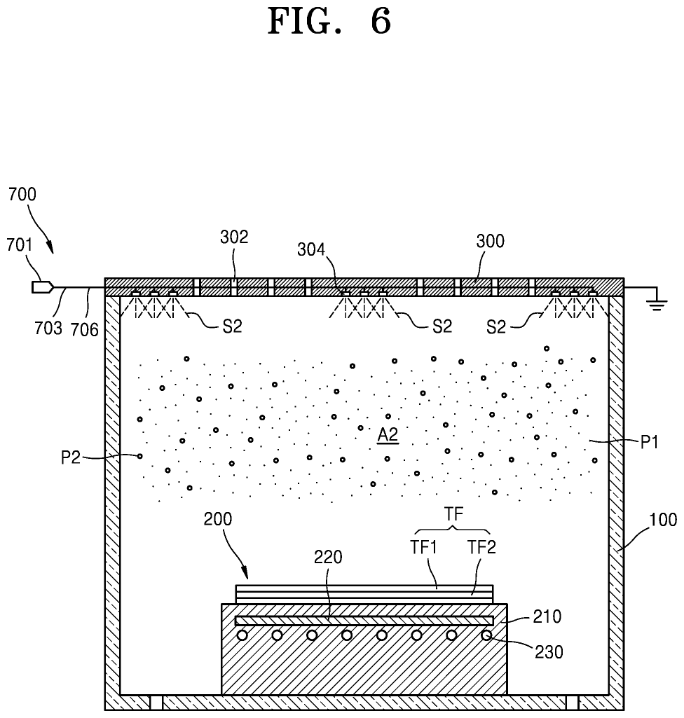

FIGS. 4 to 6 are cross-sectional views of some elements of the substrate processing apparatus, according to embodiments. Specifically, FIG. 4 is a cross-sectional view illustrating the interior of the plasma space A1 of the substrate processing apparatus 10 of FIG. 1. Specifically, FIG. 5 is a cross-sectional view illustrating the interior of the buffer space A3 of the substrate processing apparatus 10 of FIG. 1. Specifically, FIG. 6 is a cross-sectional view illustrating the interior of the processing space A2 of the substrate processing apparatus 10 of FIG. 1.

Referring to FIG. 4, the first gas supplier 800 may supply the first source gas S1 to the plasma space A1. The first source gas S1 may generate plasma P in the plasma space A1.

In some embodiments, the plasma P may include ions and/or neutral gas (radicals) generated by the first source gas S1. For example, when the first source gas S1 includes NF₃ gas, the plasma P may include fluorine radicals and/or NF₄_{⁺} ions.

In some embodiments, the plasma P may include the first process gas P1. The first process gas P1 may be gas that will later move to the processing space A2 and directly participate in an etching process. That is, the first process gas P1 may include an etching material. For example, the first process gas P1 may include a neutral gas (radicals). For example, the first process gas P1 may include fluorine radicals.

That is, in some embodiments, the first source gas S1 supplied by the first gas supplier 800, the plasma P generated by the first source gas S1, and the first process gas P1 included in the plasma P may be present in the plasma space A1.

The amount of the first source gas S1 supplied to the plasma space A1 may be adjusted by the first gas supplier 800. That is, the amount of the first source gas S1 supplied to the plasma space A1 may is increased or decreased by the first gas supplier 800.

The amount of the first process gas P1 supplied to the plasma space A1 may be adjusted by the first gas supplier 800. For example, when the amount of the first source gas S1 supplied to the plasma space A1 is increased or decreased by the first gas supplier 800, the amount of the first process gas P1 supplied to the plasma space A1 may also be increased or decreased.

Referring to FIG. 5, the ion filter 500 may filter the remaining plasma P in the plasma space A1 except for the first process gas P1, so that only the first process gas P1 is supplied to the processing space A2. Specifically, the ion filter 500 may electrically filter the remaining plasma P except for the first process gas P1, so that only the first process gas P1 is supplied to the processing space A2. For example, the ion filter 500 may be electrically grounded to filter ions in the plasma P and pass electrically neutral radicals, that is, the first process gas P1. That is, the ion filter 500 may filter the plasma P so that only the first process gas P1 including radicals is supplied to the processing space A2.

In some embodiments, the substrate processing apparatus 10 may further include a buffer space A3 disposed between the plasma space A1 and the processing space A2. The buffer space A3 may be a space in which the first process gas P1 generated in the plasma space A1 is uniformly distributed before the first process gas P1 is supplied to the processing space A2. In some embodiments, when the substrate processing apparatus 10 further includes an ion filter 500, the ion filter 500 may be disposed between the plasma space A1 and the buffer space A3. Therefore, the first process gas P1 in the plasma P may be supplied to the buffer space A3 by the ion filter 500, and the first process gas P1 may be uniformly distributed in the buffer space A3.

Referring to FIG. 6, the second gas supplier 700 may supply the second source gas S2 to the processing space A2. The second source gas S2 may include the second process gas P2. The second source gas S2 may generate the second process gas P2.

The amount of the second source gas S2 supplied to the processing space A2 may be adjusted by the second gas supplier 700. That is, the amount of the second source gas S2 supplied to the processing space A2 may be increased or decreased by the second gas supplier 700.

The amount of the second process gas P2 supplied to the processing space A2 may be adjusted by the second gas supplier 700. For example, when the amount of the second source gas S2 supplied is increased or decreased by the second gas supplier 700, the amount of the second process gas P2 may also be increased or decreased.

In some embodiments, the second source gas S2 may include at least one selected from F₂, HF, SF₆, SiF₄, XeF₂, and NF₃. The second source gas S2 may supply the second process gas P2 to the processing space A2. The second process gas P2 may be directly supplied to the processing space A2 and may participate in an etching process. That is, the second source gas S2 may include an etching material. For example, the second source gas S2 may include F₂.

In some embodiments, the first process gas P1 that has passed through the ion filter 500 and the buffer space A3 may be supplied to the processing space A2. The first process gas P1 may perform an etching process in the processing space A2. That is, the first process gas P1 and the second process gas P2 may be present together in the processing space A2.

In some embodiments, after the first process gas P1 is supplied to the processing space A2, the second process gas P2 may be supplied to the processing space A2 through the second gas supplier 700. In some embodiments, after the second process gas P2 is supplied to the processing space A2 through the second gas supplier 700, the first process gas P1 may be supplied to the processing space A2.

In some embodiments, the first gas supplier 800 that supplies the first source gas S1 and the second gas supplier 700 that supplies the second source gas S2 may be separated from each other. That is, the first gas supplier 800 that supplies the first source gas S1 generating the plasma P including the first process gas P1 and the second gas supplier 700 that supplies the second source gas S2 supplying the second process gas P2 may be separated from each other. That is, the first process gas P1 may be supplied to the plasma space A1 and moved to the processing space A2, and the second process gas P2 may be directly supplied to the processing space A2.

In some embodiments, the interior of the buffer space A3 and the processing space A2 may be coated with nickel (Ni). The nickel (Ni) coating may adjust the flow rate of the first process gas P1 by absorbing the first process gas P1 generated in and supplied from the plasma space A1.

In some embodiments, a support plate 210 and an etch target layer TF may be disposed in the processing space A2. The etch target layer TF may be supported by the support plate 210 and may participate in a process performed within the processing space A2. For example, the etch target layer TF may be supported by the support plate 210 and may participate in an etching process. The support plate 210 may is raised or lowered so as to be closer to or farther away from a ceiling of the processing space A2.

In some embodiments, the etch target layer TF may include a plurality of etch target layers having different etching conditions. For example, the etch target layer TF may include a first etch target layer TF1 and a second etch target layer TF2. In some embodiments, the first etch target layer TF1 and the second etch target layer TF2 may have different etching conditions. For example, the first etch target layer TF1 and the second etch target layer TF2 may be etched by using different etchants. For example, the first etch target layer TF1 may be etched by fluorine radicals, and the second etch target layer TF2 may be etched by F₂. For example, the first etch target layer TF1 may include a silicon (Si) layer, and the second etch target layer TF2 may include a silicon-germanium (SiGe) layer. For example, the first etch target layer TF1 and the second etch target layer TF2 may each include a SiGe layer having different Si compositions.

In some embodiments, the first etch target layer TF1 and the second etch target layer TF2 may be etched by the first process gas P1 and the second source gas S2, respectively. Specifically, the process of etching the first etch target layer TF1 may be performed by using the first process gas P1. Specifically, the process of etching the second etch target layer TF2 may be performed by using the second process gas P2. For example, the process of etching the first etch target layer TF1 may be performed by using the first process gas P1 including fluorine radicals. For example, the process of etching the first etch target layer TF1 including the Si layer may be performed by using the first process gas P1 including fluorine radicals. For example, the process of etching the second etch target layer TF2 may be performed by using the second process gas P2 including F₂ molecules. For example, the process of etching the second etch target layer TF2 including the SiGe layer may be performed by using the second process gas P2 including F₂ molecules.

In some embodiments, the process of etching the first etch target layer TF1 may be controlled by the first gas supplier 800. The process of etching the second etch target layer TF2 may be controlled by the second gas supplier 700. For example, when the amount of the first source gas S1 supplied is increased by the first gas supplier 800, the amount of the first process gas P1 supplied may increase and the degree of etching of the first etch target layer TF1 may increase. In contrast, when the amount of the first source gas S1 supplied is decreased by the first gas supplier 800, the amount of the first process gas P1 supplied may decrease and the degree of etching of the first etch target layer TF1 may decrease. For example, when the amount of the second source gas S2 supplied is increased by the second gas supplier 700, the amount of the second process gas P2 supplied may increase and the degree of etching of the second etch target layer TF2 may increase. In contrast, when the amount of the second source gas S2 supplied is decreased by the second gas supplier 700, the amount of the second process gas P2 supplied may decrease and the degree of etching of the second etch target layer TF2 may decrease.

In some embodiments, the etch selectivity of the first etch target layer TF1 and the second etch target layer TF2 may be adjusted by the first gas supplier 800 and the second gas supplier 700. Specifically, the etch selectivity of the first etch target layer TF1 relative to the second etch target layer TF2 may be adjusted by the first gas supplier 800 and the second gas supplier 700. Specifically, the etch selectivity of the second etch target layer TF2 relative to the first etch target layer TF1 may be adjusted by the first gas supplier 800 and the second gas supplier 700. For example, when the ratio of the first source gas S1 to the second source gas S2 is increases by the first gas supplier 800 and the second gas supplier 700, the ratio of the first process gas P1 to the second process gas P2 may increase, and thus, the etch selectivity of the first etch target layer TF1 relative to the second etch target layer TF2 may increase. For example, when the ratio of the second source gas S2 to the first source gas S1 is increases by the first gas supplier 800 and the second gas supplier 700, the ratio of the second process gas P2 to the first process gas P1 may increase, and thus, the etch selectivity of the second etch target layer TF2 relative to the first etch target layer TF1 may increase.

In some embodiments, the pressure at which the process is performed in the substrate processing apparatus 10 may be about 0.1 torr to about 11 torr. In some embodiments, the temperature of the support plate 210 in the processing space A2 of the substrate processing apparatus 10 may be about 40° C. or less. For example, the temperature of the support plate 210 may be about −20° C. to about 40° C. In some embodiments, the temperature of the substrate processing apparatus 10 may be about 60° C. or higher. For example, the temperature of the substrate processing apparatus 10 may be about 60° C. to about 110° C.

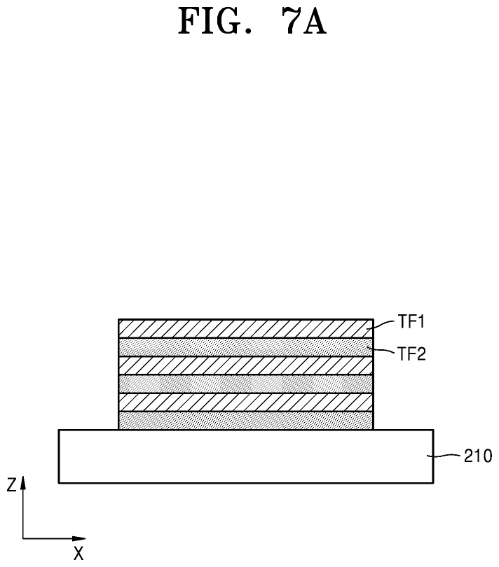

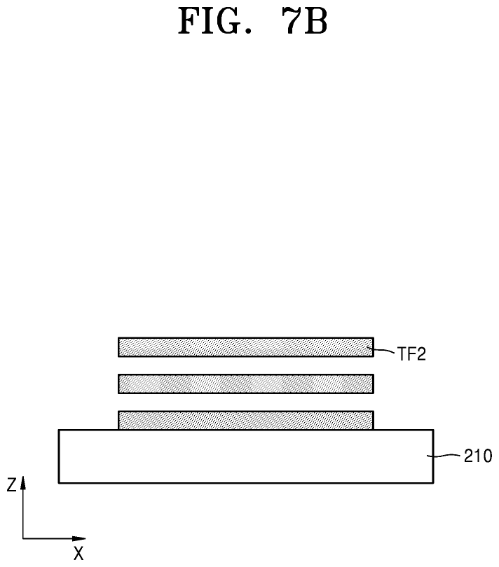

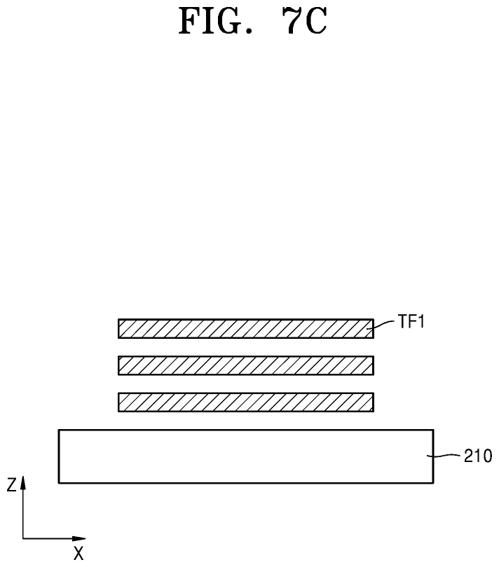

FIGS. 7A to 7C are cross-sectional views illustrating the process of etching the etch target layer TF, according to embodiments. Specifically, FIGS. 7A to 7C are cross-sectional views illustrating the process of etching the first etch target layer TF1 and the second etch target layer TF2, which are stacked in a vertical direction (a Z direction).

Referring to FIGS. 7A to 7C, the first etch target layer TF1 and the second etch target layer TF2 may be stacked on the support plate 210 in the vertical direction (the Z direction). As described above, the etch selectivity of the first etch target layer TF1 and the second etch target layer TF2 may be adjusted by the first gas supplier 800 and the second gas supplier 700.

For example, as illustrated in FIG. 7B, when the amount of the first source gas (see S1 of FIGS. 4 to 6) supplied is increased by the first gas supplier 800, the amount of the first process gas (see P1 of FIGS. 4 to 6) supplied may increase, and thus, the degree of etching of the first etch target layer TF1 may increase. That is, when the ratio of the first source gas S1 to the second source gas (see S2 of FIGS. 4 to 6) is increased by the first gas supplier 800 and the second gas supplier 700, the ratio of the first process gas P1 to the second process gas (see P2 of FIGS. 4 to 6) may increase, and thus, the etch selectivity of the first etch target layer TF1 relative to the second etch target layer TF2 may increase.

For example, as illustrated in FIG. 7C, when the amount of the second source gas S2 supplied is increased by the second gas supplier 700, the amount of the second process gas P2 supplied may increase and the degree of etching of the second etch target layer TF2 may increase. That is, when the ratio of the second source gas S2 to the first source gas S1 is increases by the first gas supplier 800 and the second gas supplier 700, the ratio of the second process gas P2 to the first process gas P1 may increase, and thus, the etch selectivity of the second etch target layer TF2 relative to the first etch target layer TF1 may increase.

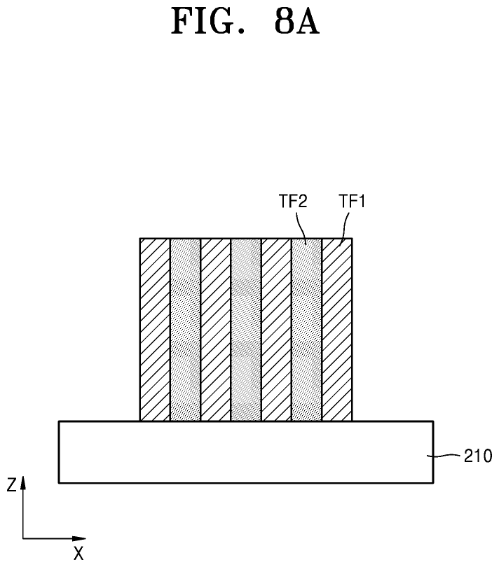

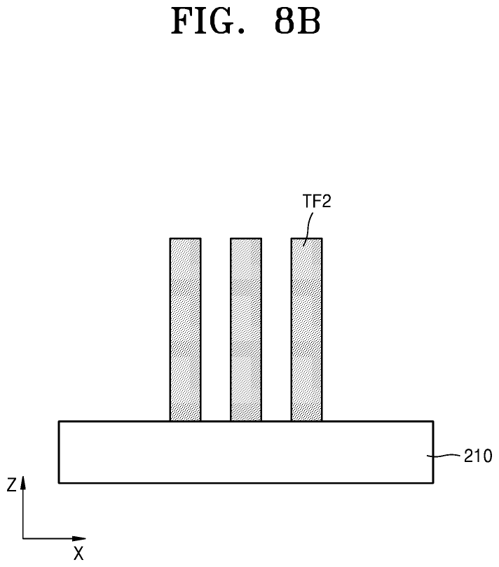

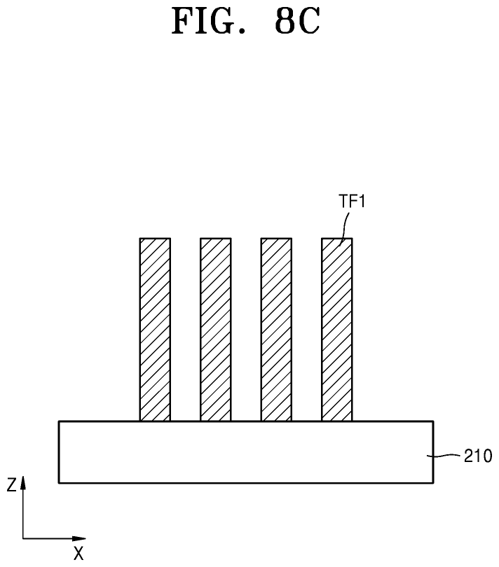

FIGS. 8A to 8C are cross-sectional views illustrating a process of etching an etch target layer, according to embodiments. Specifically, FIGS. 8A to 8C are cross-sectional views illustrating the process of etching the first etch target layer TF1 and the second etch target layer TF2, which are stacked in a horizontal direction (an X direction).

Referring to FIGS. 8A to 8C, the first etch target layer TF1 and the second etch target layer TF2 may be stacked on the support plate 210 in the horizontal direction (the X direction). Similar to FIG. 7A, the etch selectivity of the first etch target layer TF1 and the second etch target layer TF2 may be adjusted by the first gas supplier 800 and the second gas supplier 700.

For example, similar to FIG. 7B, as illustrated in FIG. 8B, when the amount of the first source gas (see S1 of FIGS. 4 to 6) supplied is increased by the first gas supplier 800, the amount of the first process gas (see P1 of FIGS. 4 to 6) supplied may increase, and thus, the degree of etching of the first etch target layer TF1 may increase. That is, when the ratio of the first source gas S1 to the second source gas (see S2 of FIGS. 4 to 6) is increased by the first gas supplier 800 and the second gas supplier 700, the ratio of the first process gas P1 to the second process gas (see P2 of FIGS. 4 to 6) may increase, and thus, the etch selectivity of the first etch target layer TF1 relative to the second etch target layer TF2 may increase.

For example, similar to FIG. 7C, as illustrated in FIG. 8C, when the amount of the second source gas S2 supplied is increased by the second gas supplier 700, the degree of etching of the second etch target layer TF2 may increase. That is, when the ratio of the second source gas S2 to the first source gas S1 is increases by the first gas supplier 800 and the second gas supplier 700, the ratio of the second process gas P2 to the first process gas P1 may increase, and thus, the etch selectivity of the second etch target layer TF2 relative to the first etch target layer TF1 may increase.

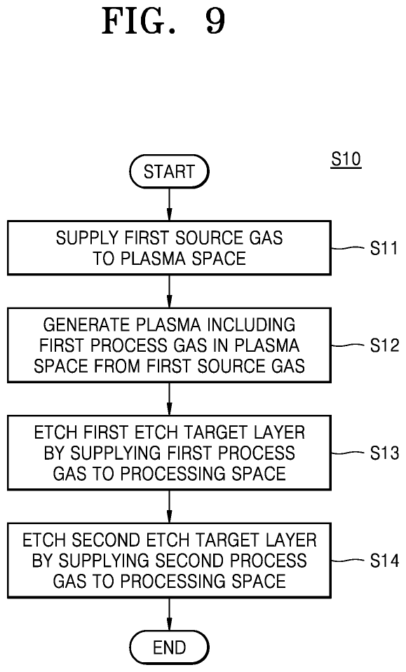

FIG. 9 is a flowchart showing a substrate processing method S10 according to embodiments.

Referring to FIGS. 4 and 9 together, the first source gas S1 may be supplied to the plasma space A1 (S11). The operation S11 of supplying the first source gas S1 may be performed by the first gas supplier 800.

Continuing to refer to FIGS. 4 and 9, the first source gas S1 may generate plasma P including the first process gas P1 in the plasma space A1 (S12).

Continuing to refer to FIGS. 6 and 9, the first etch target layer TF1 may be etched by supplying the first process gas P1 to the processing space A2 (S13).

Continuing to refer to FIGS. 6 and 9, the second etch target layer TF2 may be etched by supplying the second process gas P2 to the processing space A2 (S14). The operation of supplying the second process gas P2 may be performed by the second gas supplier 700.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a plasma space;
a processing space;
a first gas supplier configured to supply first source gas to the plasma space; and
a second gas supplier configured to supply second process gas to the processing space,
wherein the first source gas supplies first process gas for etching a first etch target layer in the processing space,
the second process gas etches a second etch target layer in the processing space, and
the first gas supplier and the second gas supplier are separated from each other.

2. The substrate processing apparatus of claim 1, wherein the first source gas includes one or more selected from NF₃, SF₆, SiF₄, and XeF₂, and
the second process gas includes fluorine gas (F₂).

3. The substrate processing apparatus of claim 1, wherein the first process gas includes fluorine (F) radicals.

4. The substrate processing apparatus of claim 1, further comprising an ion filter disposed between the plasma space and the processing space,
wherein the first process gas passes through the ion filter and is supplied to the processing space.

5. The substrate processing apparatus of claim 1, further comprising a buffer space disposed between the plasma space and the processing space,
wherein the first process gas passes through the buffer space and is supplied to the processing space.

6. The substrate processing apparatus of claim 1, wherein the second process gas does not pass through the plasma space.

7. The substrate processing apparatus of claim 1, wherein the first etch target layer comprises a silicon (Si) layer, and
the second etch target layer comprises a silicon-germanium (SiGe) layer.

8. A substrate processing apparatus comprising:
a plasma space;
a processing space in which a first etch target layer and a second etch target layer are disposed;
a first gas supplier configured to supply first source gas to the plasma space; and
a second gas supplier configured to supply second source gas to the processing space,
wherein the first source gas generates first process gas in the plasma space,
the second source gas supplies second process gas to the processing space,
the first process gas etches the first etch target layer,
the second process gas etches the second etch target layer, and
a degree of etching of the second etch target layer relative to the first etch target layer is adjusted by adjusting a ratio of the second source gas to the first source gas.

9. The substrate processing apparatus of claim 8, wherein the first etch target layer comprises a silicon (Si) layer, and
the second etch target layer comprises a silicon-germanium (SiGe) layer.

10. The substrate processing apparatus of claim 8, wherein the first gas supplier and the second gas supplier are separated from each other.

11. The substrate processing apparatus of claim 8, wherein the first source gas includes one or more selected from NF₃, SF₆, SiF₄, and XeF₂, and
the second source gas includes one or more selected from F₂, HF, SF₆, SiF₄, XeF₂, and NF₃.

12. The substrate processing apparatus of claim 8, wherein the first process gas includes fluorine (F) radicals.

13. The substrate processing apparatus of claim 8, wherein the second process gas does not pass through the plasma space.

14. The substrate processing apparatus of claim 8, further comprising an ion filter disposed between the plasma space and the processing space,
wherein the first process gas passes through the ion filter and is supplied to the processing space.

15. A substrate processing method comprising:
supplying first source gas to a plasma space;
allowing the first source gas to generate first process gas in the plasma space;
etching a first etch target layer by supplying the first process gas to a processing space;
etching a second etch target layer by supplying, to the processing space, second source gas that supplies second process gas; and
adjusting a degree of etching of the second etch target layer relative to the first etch target layer by adjusting a ratio of the second source gas to the first source gas.

16. The substrate processing method of claim 15, wherein the first etch target layer comprises a silicon (Si) layer, and
the second etch target layer comprises a silicon-germanium (SiGe) layer.

17. The substrate processing method of claim 15, wherein the first source gas includes one or more selected from NF₃, SF₆, SiF₄, and XeF₂, and
the second source gas includes one or more selected from F₂, HF, SF₆, SiF₄, XeF₂, and NF₃.

18. The substrate processing method of claim 15, wherein the first source gas is supplied through a first gas supplier,
the second source gas is supplied through a second gas supplier, and
the first gas supplier and the second gas supplier are separated from each other.

19. The substrate processing method of claim 15, wherein the first process gas passes through an ion filter disposed between the plasma space and the processing space and is supplied to the processing space.

20. The substrate processing method of claim 15, wherein the first process gas includes fluorine (F) radicals, and
the second process gas includes fluorine gas (F₂).
